(19) United States
(12) Patent Application Publication
(10) Pub. No.: US 2026/0324117 A1
(43) Pub. Date: Oct. 15, 2026

(54) IMAGE SENSING DEVICE

(71) Applicant: SK hynix Inc., Icheon-si (KR)

(72) Inventors: Da Yea BAEK, Icheon-si (KR); Hyun Soo LIM, Icheon-si (KR)

(21) Appl. No.: 19/430,157

(22) Filed: Dec. 22, 2025

(30) Foreign Application Priority Data
Apr. 11, 2025 (KR) 10-2025-0047317

(51) Int. Cl. H10F 39/00; H10F 39/18

(52) U.S. Cl. CPC H10F 39/807; H10F 39/014; H10F 39/182

(57) ABSTRACT

Image sensing devices are disclosed. In an embodiment, an image sensing device includes a unit pixel and a pixel isolator. The unit pixel includes a first photoelectric conversion region and a second photoelectric conversion region spaced apart from each other in a substrate that includes a first surface upon configured to receive incident light and a second surface facing or opposite to the first surface. The pixel isolator is disposed in a trench recessed from the second surface into the substrate, and includes a first insulation region having a first width and a second insulation region having a second width different from the first width and disposed between the first photoelectric conversion region and the second photoelectric conversion region.

### PRIORITY CLAIM AND CROSS-REFERENCE TO RELATED APPLICATION

This patent document claims the priority and benefits of Korean patent application No. 10-2025-0047317, filed on Apr. 11, 2025, the disclosure of which is incorporated herein by reference in its entirety as part of the disclosure of this patent document.

### TECHNICAL FIELD

The technology and implementations disclosed in this patent document generally relate to an image sensing device capable of generating image data by sensing light.

### BACKGROUND

An image sensing device captures optical images by converting light into electrical signals using a photosensitive semiconductor material that reacts to light. With advancements in industries such as automotive, medical, computer and communication industries, the demand for high-performance image sensing devices is growing across various fields such as smartphones, digital cameras, game machines, IoT (Internet of Things), robots, security cameras and medical micro cameras.

The image sensing device may be roughly divided into charge Coupled Device (CCD) image sensing devices and complementary metal oxide semiconductor (CMOS) image sensing devices. CCD image sensing devices offer a better image quality, but they tend to consume more power and are larger as compared to CMOS image sensing devices. CMOS image sensing devices are smaller in size and consume less power than CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device with improved autofocus performance.

Various embodiments of the disclosed technology relate to an image sensing device with improved productivity.

In an embodiment of the disclosed technology, an image sensing device may include: a substrate including a first surface configured to receive incident light and a second surface opposite to the first surface, a unit pixel including a first photoelectric conversion region configured to generate an electrical signal in response to the incident light and a second photoelectric conversion region spaced apart from the first photoelectric conversion region and configured to generate an electrical signal in response to the incident light; and a pixel isolator disposed in a trench recessed from the second surface into the substrate, the pixel isolator including a first insulation region having a first width along a direction parallel to the substrate and a second insulation region having a second width different from the first width and disposed between the first photoelectric conversion region and the second photoelectric conversion region.

In another embodiment of the disclosed technology, an image sensing device may include: a unit pixel that includes a first semiconductor region including a first photoelectric conversion region configured to detect light, a second semiconductor region including a second photoelectric conversion region configured to detect light and spaced apart from the first semiconductor region in a first direction, and a semiconductor bridge region to connect the first semiconductor region and the second semiconductor region; and a pixel isolator formed to surround the unit pixel and structured to include a first insulation region having a first width and disposed along a side surface of the unit pixel and a second insulation region having a second width less than the first width and disposed along another side surface of the unit pixel.

In another embodiment of the disclosed technology, an image sensing device may include: a substrate including a first surface configured to receive incident light and a second surface opposite to the first surface, a unit pixel that is supported by the substrate and includes a first semiconductor region including a first photoelectric conversion region configured to detect light and a second surface facing or opposite to the first surface, a second semiconductor region including a second photoelectric conversion region configured to detect light and spaced apart from the first semiconductor region in a first direction, and a semiconductor bridge region disposed between the first semiconductor region and the second semiconductor region; a pixel isolator disposed in a trench recessed from the second surface into the substrate and including an insulation layer surrounding the unit pixel and a filler layer surrounding the insulation layer; and an interconnect layer disposed on the second surface of the substrate. The insulation layer may include: a first insulation region having a first width in a circumferential region; and a second insulation region having a second width in a protrusion region protruding from the circumferential region to the semiconductor bridge region in a second direction perpendicular to the first direction.

It is to be understood that both the foregoing general description and the following detailed description of the disclosed technology are illustrative and explanatory and are intended to provide further explanation of the disclosed technology as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic diagram illustrating an example of an image sensing device based on some embodiments of the disclosed technology.

FIG. 2 is a circuit diagram illustrating an example of a unit pixel included in the image sensing device based on some embodiments of the disclosed technology.

FIG. 3 is a plan view illustrating an example of the image sensing device based on some embodiments of the disclosed technology.

FIGS. 4A and 4B are cross-sectional views illustrating examples of the image sensing device based on some embodiments of the disclosed technology.

FIG. 5 is a plan view illustrating an example of the image sensing device based on some embodiments of the disclosed technology.

FIG. 6 is a plan view illustrating an example of the image sensing device based on some embodiments of the disclosed technology.

FIG. 7 is a plan view illustrating an example of the image sensing device based on some embodiments of the disclosed technology.

FIGS. 8A-8D are cross-sectional views illustrating examples of a method of manufacturing the image sensing device based on some embodiments of the disclosed technology.

### DETAILED DESCRIPTION

This patent document provides implementations and examples of an image sensing device capable of generating image data by sensing light that may be used in configurations to substantially address one or more technical or engineering issues and to mitigate limitations or disadvantages encountered in some other image sensing devices. Some implementations of the disclosed technology relate to an image sensing device with improved autofocus performance. Some implementations of the disclosed technology relate to an image sensing device with improved productivity. In recognition of the issues above, some embodiments of the disclosed technology provide an image sensing device that enables the insulation layers surrounding the unit pixels to have different widths depending on positions of the insulation layers. This configuration alleviates difficulties in forming an impurity region, enhancing manufacturing efficiency. The disclosed technology provides the image sensing device that has higher autofocus performance by relatively increasing the doping concentration of the impurity region. Some embodiments of the disclosed technology provide the image sensing device that has a region in which a width of the insulation layer varies depending on the type of the unit pixel, allowing the image sensing device to have a more uniform sensitivity across the image sensing device.

Reference will now be made in detail to the embodiments of the disclosed technology, examples of which are illustrated in the accompanying drawings. Wherever possible, the same reference numbers will be used throughout the drawings to refer to the same or like parts. While the disclosed technology is susceptible to various modifications and alternative forms, specific embodiments thereof are shown by way of example in the drawings. However, the disclosed technology should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

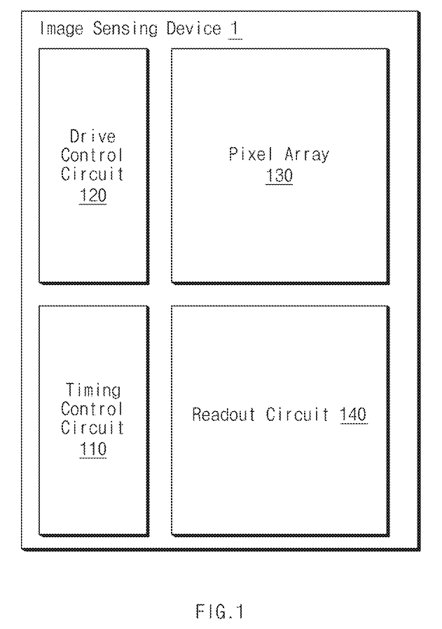

FIG. 1 is a schematic diagram illustrating an example of an image sensing device 1 based on some embodiments of the disclosed technology.

Referring to FIG. 1, the image sensing device 1 according to an exemplary embodiment of the disclosed technology may include a timing control circuit 110, a drive control circuit 120, a pixel array 130, and a readout circuit 140. The constituent components of the image sensing device 1 illustrated in FIG. 1 are discussed by way of example only, and this patent document encompasses numerous other changes, substitutions, variations, alterations, and modifications. In some embodiments described in this patent document, the word “pixel” can be used to indicate an image sensing pixel that is structured to detect incident light to generate electrical signals carrying images in the incident light.

The timing control circuit 110 may provide a timing signal and a control signal to at least one of the drive control circuit 120 and the readout circuit 140.

The drive control circuit 120 may activate the pixel array 130 to perform specific operations on pixels included in a corresponding row based on the timing signal and the control signals provided from the timing control circuit 110.

In some implementations, the drive control circuit 120 may select at least one pixel arranged in at least one row of the pixel array 130, and may provide the selected pixel with a control signal for performing a specific operation. The drive control circuit 120 may generate a row selection signal to select at least one row from among a plurality of rows. When the drive control circuit 120 selects a specific row from among the plurality of rows to perform a specific operation, the drive control circuit 120 may not perform the specific operation on a row adjacent to the selected specific row.

The pixels of the row selected by the drive control circuit 120 may sequentially transfer analog reference signals and image signals to the readout circuit 140. The reference signal may be an electrical signal provided to the readout circuit 140 when a floating diffusion region of each pixel is reset to a power-supply voltage VDD. The image signal may be an electrical signal provided to the readout circuit 140 when photocharges generated by each pixel are accumulated in the floating diffusion region (FD).

The reference signal may be a signal indicating unique pixel noise of each pixel, and the reference signal and the image signal may be collectively referred to as a pixel signal as necessary.

The pixel array 130 may include a plurality of pixels arranged in a plurality of rows and a plurality of columns. The plurality of pixels may be connected to the drive control circuit 120 through a plurality of row lines extending in the row direction. The plurality of pixels may be connected to the readout circuit 140 through a plurality of column lines extending in the column direction. The pixel array 130 may include at least one pixel 200 arranged in the row direction and the column direction. For example, the pixel array 130 may be arranged in a two-dimensional (2D) pixel array (or matrix configuration) in which a plurality of unit pixels includes rows and columns.

The plurality of unit pixels included in the pixel array 130 may convert optical signals into electrical signals (pixel signals), and may be connected to a specific internal pixel circuit.

The pixel array 130 may receive pixel control signals including a selection signal, a reset signal, a transfer signal, etc. from the drive control circuit 120. At least one pixel included in the row that is selected by the drive control circuit 120 according to the pixel control signal may perform a specific operation in response to the selection signal, the reset signal, and the transfer signal.

Each of the plurality of pixels included in the pixel array 130 may output a pixel signal in response to incident light received from the outside. Each of the plurality of pixels may be arranged in a two-dimensional (2D) structure. For example, each of the plurality of pixels may be arranged in a matrix structure. The plurality of pixels may be arranged in a first direction and a second direction. For example, the plurality of pixels may be arranged in a row direction and a column direction.

Among light incident upon the pixel, light of a specific wavelength band (e.g., red light, green light, or blue light) may pass through an optical filter arranged in an active pixel, and light having penetrated the optical filter may be focused onto at least one photoelectric conversion element. The photoelectric conversion element may generate photocharges in response to incident light. An electrical signal may be generated by the pixel in response to the amount of generated photocharges.

When the pixel operates in a state where the amount of incident light is very small or there is no incident light (hereinafter referred to as a dark condition), the pixel may generate a dark signal. Signals generated under dark conditions may be signals corresponding to a noise component generated inside the image sensing device 1.

As the number of pixels included in the pixel array 130 increases and the area of the entire pixel array 130 increases, a deviation of noise components of pixels may increase depending on positions of the pixels in the pixel array 130. As the deviation of noise components increase, the quality of an image obtained by a plurality of pixel signals generated from the pixel array 130 may decrease.

The readout circuit 140 may sample electrical signals output from the pixel array 130, may convert the sampled electrical signals into digital signals, and may output the digital signals to an image signal processor (ISP). The readout circuit 140 may include, for example, a correlated double sampler (CDS), an analog-to-digital converter (ADC), an output buffer, a column driver, etc.

For example, the CDS may receive the reference signal and the image signal, each of which corresponds to the columns of the pixel array 130, and may sample levels of the reference signal and the image signal. In the image sensing device designed to use CMOS(s), the CDS may sample a pixel signal twice to remove a difference between these two samples, and may perform correlated double sampling to remove undesired offset values of pixels such as fixed noise. For example, the CDS may compare pixel output voltages obtained before and after photocharges generated by incident light are accumulated in the floating diffusion region to remove undesired offset values, so that the pixel output voltages based on the incident light can be measured.

The CDS may transmit reference signals and image signals, which are generated in columns based on a timing signal and a control signal of the timing control circuit 110, to the ADC as CDS signals.

The ADC may convert analog CDS signals received from the CDS into digital signals, and may output the resultant digital signals.

The output buffer may temporarily hold and output digital signals provided from the ADC.

The column driver may select columns from the output buffer based on a timing signal and a control signal of the timing control circuit 110, and may control the temporarily held digital signals to be output according to the selection order.

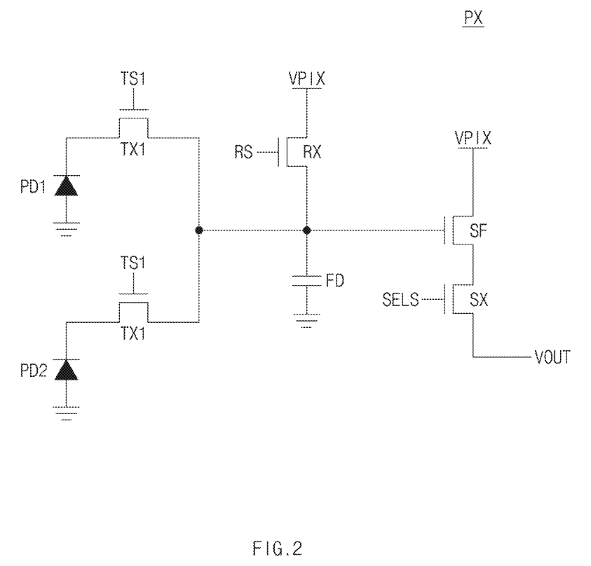

FIG. 2 is a circuit diagram illustrating an example of a unit pixel (PX) included in the image sensing device 1 based on some embodiments of the disclosed technology.

Referring to FIG. 2, the unit pixel (PX) is included in the pixel array 130 (see FIG. 1), and a plurality of unit pixels may be repeatedly arranged in the row direction and the column direction of the pixel array 130 (see FIG. 1).

One unit pixel (PX) may include a first photoelectric conversion element (PD1), a second photoelectric conversion element (PD2), a first transfer transistor (TX1), a second transfer transistor (TX2), a reset transistor (RX), an amplification transistor (SF), and a selection transistor (SX). However, unlike the illustrated example, in certain other implementations, at least one of the reset transistor (RX), the amplification transistor (SF), and the selection transistor (SX) may be omitted from the unit pixel (PX), or an additional transistor may be included in the unit pixel (PX).

The first photoelectric conversion element (PD1) and the second photoelectric conversion element (PD2) may respond to incident light to generate photocharges and the amount of the generated photocharges vary depending on the intensity of the received incident light. For example, the first photoelectric conversion element (PD1) and the second photoelectric conversion element (PD2) may be P-N junction photodiodes, and may be structured and operated to generate photocharges in proportion to the amount of incident light. Each of the first photoelectric conversion element (PD1) and the second photoelectric conversion element (PD2) may be implemented in various photosensing devices, such as a phototransistor, a photogate, a pinned photodiode, or a combination thereof. In the example in FIG. 2, one unit pixel (PX) processes a combination of photocharges (e.g., electrons) generated using two photoelectric conversion elements and outputs an electrical signal as the unit pixel output from the electrons from two photoelectric conversion elements, performance of the image sensing device can be improved.

In the example in FIG. 2, one common floating diffusion region (FD) is provided to collect the photocharges from the two photoelectric conversion elements PD1 and PD2. The first transfer transistor (TX1) may be coupled to the first photoelectric conversion element (PD1) to transfer photocharges generated by the first photoelectric conversion element (PD1) to the floating diffusion region (FD) in response to a first transfer control signal (TS1), and the second transfer transistor (TX2) may be coupled to the second photoelectric conversion element (PD2) to transfer photocharges generated by the second photoelectric conversion element (PD2) to the floating diffusion region (FD) in response to a second transfer control signal (TS2). When each of the first transfer transistor (TX1) and the second transfer transistor (TX2) is turned on, photocharges generated by each of the first photoelectric conversion element (PD1) and the second photoelectric conversion element (PD2) may be transferred to one floating diffusion region (FD), and may be accumulated and stored in the floating diffusion region (FD).

A reset transistor (RX) may be coupled to the floating diffusion region (FD) to periodically reset the photocharges accumulated in the floating diffusion region (FD) after each readout of the floating diffusion region (FD) so that the unit pixel PX is ready for the next cycle of photosensing operation. A drain electrode of the reset transistor (RX) may be connected to the floating diffusion region (FD), and a source electrode of the reset transistor (RX) may be connected to a power-supply voltage (VPIX). When the reset transistor (RX) is turned on according to a reset control signal (RS), the power-supply voltage (VPIX) connected to the source electrode of the reset transistor (RX) may be transmitted to the floating diffusion region (FD). When the reset transistor (RX) is turned on, photocharges accumulated in the floating diffusion region (FD) are discharged, so that the floating diffusion region (FD) can be reset.

The amplification transistor (SF) may serve as a buffer amplifier, and may buffer a signal according to the photocharges accumulated in the floating diffusion region (FD). The amplification transistor (SF) may be controlled according to the amount of photocharges accumulated in the floating diffusion region (FD). The amplification transistor (SF) may amplify a potential change in the floating diffusion region (FD), and may output the amplified potential change as a pixel signal (VOUT) to a column output line.

The selection transistor (SX) has a drain terminal connected to the source terminal of the amplification transistor (SF), and may output a pixel signal (VOUT) to the CDS described in FIG. 1 through a column output line in response to a selection signal (SELS).

Although the above embodiment has disclosed an example in which photocharges generated by each of the first photoelectric conversion element (PD1) and the second photoelectric conversion element (PD2) are accumulated in the same floating diffusion region (FD) for convenience of description, other implementations are also possible. According to other embodiments, photocharges generated by the first photoelectric conversion element (PD1) may be accumulated in the first floating diffusion region, and photocharges generated by the second photoelectric conversion element (PD2) may be accumulated in the second floating diffusion region separated from the first floating diffusion region.

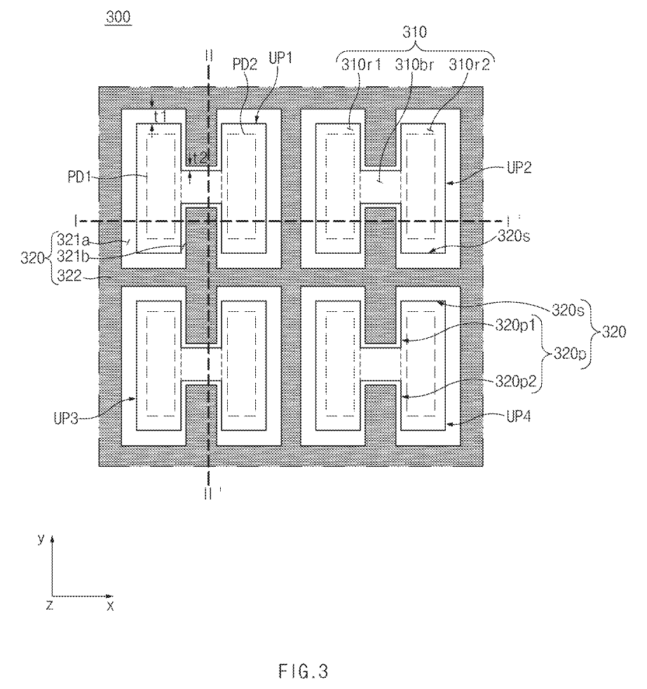

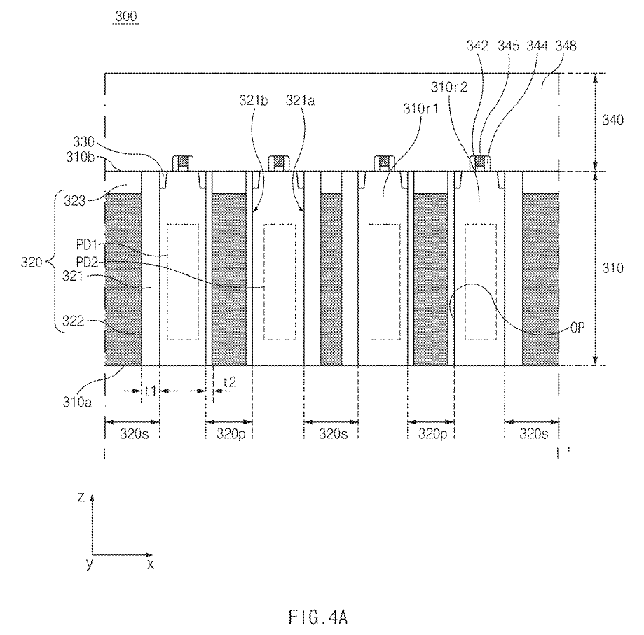

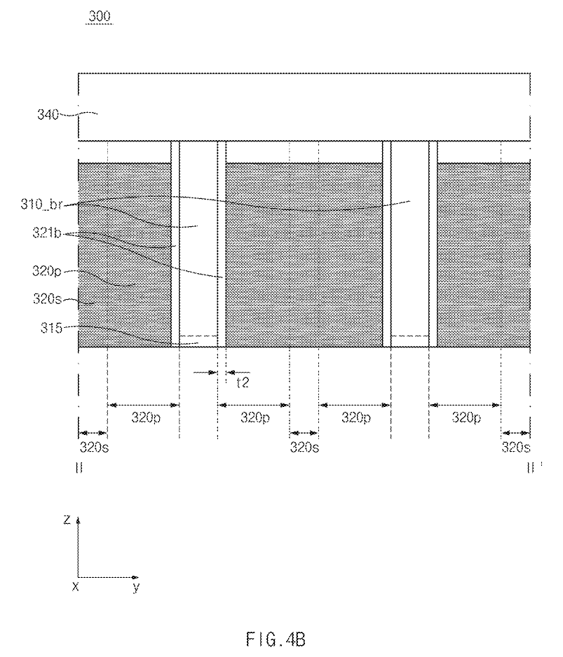

FIG. 3 is a plan view illustrating an example of the image sensing device 300 based on some embodiments of the disclosed technology. FIGS. 4A and 4B shows cross-sectional views illustrating examples of the image sensing device 300 in FIG. 3. The substrate in FIGS. 3, 4A and 4B includes a first surface in the x-y plane configured to receive incident light and a second surface in the x-y plane that is on the opposite side of the first surface of the substrate. As shown in FIGS. 4A and 4B, this substrate is represented by a substrate layer 310 which has a first surface (310a) upon which light is incident and a second surface (310b) facing or opposite to the first surface (310a) on which various circuit elements (e.g., transistors) of the unit pixel are formed or supported.

Referring to FIG. 3, the image sensing device 300 is included as part of the image sensing device 1 shown in FIG. 1, and includes a substrate, a plurality of unit pixels (e.g., UP1, UP2, UP3 and UP4) supported by the substrate and a pixel isolator 320 that is supported by the substrate and is structured to define and isolate the plurality of unit pixels.

In this example, the unit pixel is a basic unit for detecting incident light and the different unit pixels collectively form the pixel array 130 (see FIG. 1) arranged in two dimensions for sensing incident light to capture images carried by the incident light. In the example in FIG. 3, four unit pixels (i.e., first to fourth unit pixels UP1, UP2, UP3, and UP4) are illustrated as part of the plurality of unit pixels arranged in the pixel array 130 (see FIG. 1) in an enlarged view. Adjacent unit pixels among the first to fourth unit pixels (UP1, UP2, UP3, UP4) may be arranged side by side in a first direction (e.g., X-axis direction) or in a second direction (e.g., Y-axis direction) perpendicular to the first direction.

Each of the first to fourth unit pixels (UP1, UP2, UP3, UP4) may be any one of a red pixel, a green pixel, a blue pixel, and a white pixel. The red pixel may be a pixel that transmits red light of a specific wavelength band among light incident upon the unit pixel through a color filter and focuses the red light onto the photoelectric conversion element. Similarly, a green pixel, a blue pixel, and a white pixel may be pixels that converges light of a specific wavelength band (e.g., green light, blue light, or white light) onto the photoelectric conversion element. For example, the red pixel, the green pixel, the blue pixel, and the white pixel may be distinguished from each other according to the type of color filters of the corresponding unit pixel.

In some implementations, such a group of adjacent four unit pixels with different color filters may collectively form a pixel group for capturing the coloring information of an image carried by the incident light. For example, the first to fourth unit pixels (UP1, UP2, UP3, UP4) can form a color sensing pixel group in which the second unit pixel (UP2) has a red filter as a red pixel for sensing red light in the incident light, the third unit pixel (UP3) has a blue filter as a blue pixel for sensing blue light in the incident light, and each of the first unit pixel (UP1) and the fourth unit pixel (UP4) has a green filter as a green pixel for sensing green light in the incident light. This color filter arrangement forms a Bayer pattern to capture the color information of the image. However, the scope of the arrangement relationship of such pixels is not limited thereto and can also be changed in various ways.

Each of the first to fourth unit pixels (UP1, UP2, UP3, UP4) are formed on or supported by a substrate and may have substantially the same characteristics except for some structures (e.g., the type of color filter), and for convenience of description, the following description will focus on the first unit pixel (UP1). In some embodiments described in this specification, a “first unit pixel” may be referred to as a “unit pixel.” In some embodiments described in this specification, each of a “second unit pixel” or a “third unit pixel” may be referred to as an “adjacent unit pixel.”

The first unit pixel (UP1) may include a first semiconductor region (310r1) having a first photoelectric conversion region (PD1) (e.g., a photodetector) that produces photocharge in response to incident light, a second semiconductor region (310r2) having a second photoelectric conversion region (PD2) (e.g., a photodetector) that produces photocharge in response to incident light, and a semiconductor bridge region (310br) between the first semiconductor region (310r1) and the second semiconductor region (310r2). The first photoelectric conversion region (PD1) and the second photoelectric conversion region (PD2) may be substantially the same regions as those described in FIG. 2, and the first unit pixel (UP1) may be a 2PD pixel including two photoelectric conversion elements.

The first semiconductor region (310r1) and the second semiconductor region (310r2) may be arranged to be spaced apart from each other in a first direction (e.g., X-axis direction). In addition, the first photoelectric conversion region (PD1) may be arranged to be spaced apart from the second photoelectric conversion region (PD2) in the first direction (X). The first semiconductor region (310r1) may extend parallel to the second semiconductor region (310r2) in a second direction (e.g., Y-axis direction) perpendicular to the first direction (X).

A semiconductor bridge region (310br) may connect the first semiconductor region (310r1) and the second semiconductor region (310r2) to each other. In the second direction (Y), the length of the semiconductor bridge region (310br) may be shorter than the length of the first semiconductor region (310r1) and/or the length of the second semiconductor region (310r2). The first semiconductor region (310r1) may include a portion extending in the second direction (Y) from a portion connected to the semiconductor bridge region (310br). The second semiconductor region (310r2) may include a portion extending in the second direction (Y) from a portion connected to the semiconductor bridge region (310br). In some implementations, the first semiconductor region (310r1), the second semiconductor region (310r2), and the semiconductor bridge region (310br) may be connected to each other to have an “H” shape.

The pixel isolator 320 may surround the first to fourth unit pixels (UP1, UP2, UP3, UP4) and separate the unit pixels from each other. Since the first to fourth unit pixels (UP1, UP2, UP3, UP4) are spaced apart from each other by the pixel isolator 320, each unit pixel may be defined by the pixel isolator 320. The pixel isolator 320 may prevent photocharges generated by incident light incident upon each unit pixel from moving to adjacent unit pixels due to random drift. Accordingly, the pixel isolator 320 may prevent crosstalk between adjacent unit pixels and improve the image sensing.

The pixel isolator 320 may include a circumferential region (320s) surrounding the first to fourth unit pixels (UP1, UP2, UP3, UP4), and a protrusion region (320p) extending toward the semiconductor bridge region (310br) of each of the first to fourth unit pixels (UP1, UP2, UP3, UP4). Referring to FIG. 3, the circumferential region (320s) and the protrusion region (320p) may be regions separated at a certain distance on a plane with respect to the pixel isolator 320 that separates the unit pixels, each of which includes the first semiconductor region (310r1), the second semiconductor region (310r2), and the semiconductor bridge region (310br).

Therefore, the circumferential region (320s) and the protrusion region (320p) may be regions that are integrally connected. The protrusion region (320p) may extend in the second direction (Y) from the circumferential region (320s). In some implementations, the protrusion region (320p) may include a first protrusion region (320p1) and a second protrusion region (320p2) spaced apart from each other in the second direction (Y) based on the semiconductor bridge region (310br) of the unit pixel interposed therebetween. In some implementations, each of the first to fourth unit pixels (UP1, UP2, UP3, UP4) may have an “H” shape due to the protrusion region (320p) of the pixel isolator 320.

The pixel isolator 320 may include insulation layers (321a, 321b) surrounding the first to fourth unit pixels (UP1, UP2, UP3, UP4) and a filler layer 322 surrounding the insulation layers (321a, 321b).

The insulation layers (321a, 321b) may be a liner layer surrounding the side surface of the first unit pixel (UP1). Each of the insulation layers (321a, 321b) may include at least one of silicon oxide, silicon oxynitride, silicon nitride, aluminum oxide, tantalum oxide, and hafnium oxide.

The insulation layers (321a, 321b) may include a first insulation region (321a) having a first width or thickness (t1) along the direction X parallel to the substrate to cover three sides of the photoelectric conversion region (PD1, PD2) and a second insulation region (321b) having a second thickness or width (t2) along the direction X parallel to the substrate different from the first width (t1) to cover the other side of photoelectric conversion region (PD1, PD2) where the two photoelectric conversion regions PD1, and PD2 within one unit pixel face each other and between which the semiconductor bridge region (310br) is formed to connect the first semiconductor region (310r1) and the second semiconductor region (310r2). The second width (t2) may be less than the first width (t1). Each of the first insulation region (321a) and the second insulation region (321b) may be a liner layer that conformally extends along a side surface of the first unit pixel (UP1).

The first insulation region (321a) and the second insulation region (321b) may be regions that are separated at a certain distance on a plane with respect to the liner layer. Accordingly, the first insulation region (321a) may be integrally connected to the second insulation region (321b). The first insulation region (321a) may surround the first unit pixel (UP1) together with the second insulation region (321b). In some implementations, the first insulation region (321a) may include the same material as the second insulation region (321b).

The first insulation region (321a) may be located within the circumferential region (320s) of the pixel isolator 320, and the second insulation region (321b) may be located within the protrusion region (320p) of the pixel isolator 320. That is, the first insulation region (321a) may be a portion of the liner layer located within the circumferential region (320s), and the second insulation region (321b) may be a portion of the liner layer located within the protrusion region (320p). The second insulation region (321b) may be located between the first photoelectric conversion region (PD1) and the second photoelectric conversion region (PD2). The second insulation region (321b) may be located between the first semiconductor region (310r1) and the second semiconductor region (310r2).

The second insulation region (321b) may be located on the outer surface of the semiconductor bridge region (310br). In some implementations, the second insulation region (321b) may have a portion extending from a portion located on the outer surface of the semiconductor bridge region (310br) onto the outer surface of the adjacent first semiconductor region (310r1) and/or a portion extending from a portion located on the outer surface of the semiconductor bridge region (310br) onto the outer surface of the adjacent second semiconductor region (310r2). For example, the second insulation region (321b) may contact a side surface of the first semiconductor region (310r1) facing the second semiconductor region (310r2). The first insulation region (321a) may contact at least a portion of the remaining side surfaces of the first semiconductor region (310r1) except for the side surface of the first semiconductor region (310r1).

A filler layer (322) may surround the outer surfaces of the insulation layers (321a, 321b). The filler layer 322 may separate the first to fourth unit pixels (UP1, UP2, UP3, UP4) from each other together with the insulation layers (321a, 321b). The filler layer (322) may include a conductive material, for example, polycrystalline silicon. In some implementations, the filler layer (322) may be a layer for improving a defect (e.g., an electrostatic discharge (ESD) bruise) caused by photocharges generated at the outside of the first to fourth unit pixels (UP1, UP2, UP3, UP4) upon receiving a negative(-) voltage.

The filler layer (322) may be located within the circumferential region (320s). In some implementations, the filler layer 322 may have a portion extending from the circumferential region (320s) to the protrusion region (320p). In this case, the second insulation region (321b) may surround the portion extending to the protrusion region (320p) of the filler layer (322).

FIGS. 4A and 4B are cross-sectional views illustrating examples of the image sensing device 300 based on some embodiments of the disclosed technology. FIG. 4A is a cross-sectional view illustrating the image sensing device 300 taken along the line I-I’ of FIG. 3 based on some embodiments of the disclosed technology.

Referring to FIG. 4A, the image sensing device 300 according to an exemplary embodiment may include a substrate layer 310 and an interconnect layer 340 on a substrate layer 310.

The substrate layer 310 may have a first surface (310a) upon which light is incident and a second surface (310b) facing or opposite to the first surface (310a). The substrate layer 310 may include a first semiconductor region (310r1), a second semiconductor region (310r2), a semiconductor bridge region (310br), and a pixel isolator 320 described in FIG. 3 between the first surface (310a) and the second surface (320b). The bottom surfaces of the first semiconductor region (310r1), the second semiconductor region (310r2), the semiconductor bridge region (310br), and the pixel isolator 320 may be coplanar to form the first surface (310a). The top surfaces of the first semiconductor region (310r1), the second semiconductor region (310r2), the semiconductor bridge region (310br), and the pixel isolator 320 may be coplanar to form a second surface (310b). In the present specification, the term “coplanar” may mean that the surfaces of specific components are continuously connected to form the same surface.

Each of the first semiconductor region (310r1), the second semiconductor region (310r2), and the semiconductor bridge region (310br) may include silicon, germanium, silicon-germanium, a group II-VI compound semiconductor, or a group III-V compound semiconductor.

The first photoelectric conversion region (PD1) in the first semiconductor region (310r1) and the second photoelectric conversion region (PD2) in the second semiconductor region (310r2) may be spaced apart from each other in the first direction (X) between the first surface (310a) and the second surface (310b). In some implementations, the first semiconductor region (310r1), the second semiconductor region (310r2), and the semiconductor bridge region (310br) may include impurities of a first conductivity type, and the first and second photoelectric conversion regions (PD1, PD2) may include impurities of a second conductivity type different from the first conductivity type. For example, the first conductivity type may be P-type, and the second conductivity type may be N-type.

The pixel isolator 320 may be disposed in a trench (OP) that is recessed into the substrate layer 310 from the second surface (310b). In some implementations, the trench (OP) may penetrate the substrate layer 310 toward the first surface (310a) of the substrate layer 310. In this case, the bottom surface of the pixel isolator 320 may form a portion of the first surface (310a).

However, according to the embodiments, the trench (OP) may be recessed into the substrate layer 310 from the second surface (310b) by a predetermined depth. In this case, the bottom surface of the pixel isolator 320 may be located at a higher height than the first surface (310a). In FIG. 4A, the trench (OP) is illustrated as having the same width, but according to some embodiments, the trench (OP) may have a shape in which the width thereof becomes smaller in a direction from the second surface (310b) to the first surface (310a).

At the height of the substrate layer 310, a plurality of unit pixels (UP1, UP2, UP3, UP4) may be separated from each other by the pixel isolator 320.

The insulation layer 321 of the pixel isolator 320 may be disposed on a sidewall of the trench (OP). The insulation layer 321 may include a first insulation region (321a) and a second insulation region (321b) as described in FIG. 3. The first insulation region (321a) may cover at least a portion of a sidewall (e.g., a circumferential region 320s of the pixel isolator 320) facing a first side of the first semiconductor region (310r1), and may cover at least a portion of a sidewall (e.g., a circumferential region 320s of the pixel isolator 320) facing a first side of the second semiconductor region (310r2).

The second insulation region (321b) may cover at least a portion of a sidewall (e.g., the protrusion region 320p of the pixel isolator 320) facing the second side of the first semiconductor region (310r1), and may cover at least a portion of a sidewall (e.g., the protrusion region 320p of the pixel isolator 320) facing the second side of the second semiconductor region (310r2).

In order to improve damage to adjacent semiconductor regions due to the trench (OP) formation process, an impurity doping process using plasma may be performed after the pixel isolator 320 is formed. In this case, the impurity doping concentration of the semiconductor region adjacent to the insulation layer 321 having a second width (t2) that is relatively less than the first width (t1) may be increased. In addition, damage improvement efficiency may be increased in response to a subsequent voltage signal to be input to the semiconductor region in a subsequent process. Accordingly, the disclosed technology may provide the image sensing device 300 in which autofocus performance in a 2PD pixel is improved.

The filler layer 322 of the pixel isolator 320 may surround the insulation layer 321 within the trench (OP). The filler layer 322 may have a shape that fills the trench (OP) from the bottom surface of the trench (OP). The filler layer 322 may be located on the outer surface of the insulation layer 321.

In some implementations, the pixel isolator 320 may further include a capping layer 323. The capping layer 323 may be disposed between the second surface (310b) of the substrate layer 310 and the filler layer 322 within the trench (OP). For example, the side surface of the capping layer 323 may be coplanar with the side surface of the filler layer 322. The insulation layer 321 may extend from the side surface of the filler layer 322 to the side surface of the capping layer 323.

The image sensing device 300 according to the embodiments of the disclosed technology may further include a device isolator 330. The device isolator 330 may be a shallow trench isolation (STI) layer, and active regions within the unit pixel may be defined by the device isolator 330. The device isolator 330 may contact the second surface (310b) of the substrate layer 310. For example, the bottom surface of the device isolator 330 may be located at a higher height than the bottom surface of the pixel isolator 320. The device isolator 330 may include, for example, at least one of silicon oxide, silicon nitride, and silicon oxynitride.

The interconnect layer 340 may be disposed on the second surface (310b) of the substrate layer 310 to support various circuit elements for each unit pixel.

The interconnect layer 340 may include at least one gate structure (342, 344, 345) disposed on the second surface (310b), a plug (not shown) connected to the gate structures (342, 344, 345), an interconnect line (not shown) connected to the plug (not shown), and an interlayer insulation layer 348.

The gate structures (342, 344, 345) may include a gate electrode 345 on the second surface (310b), a dielectric layer 342 between the gate electrode 345 and the substrate layer 310, and a spacer 344 on a side surface of the gate electrode 345. The positions of the gate structures (342, 344, 345) may be arranged to be variously changed within the interconnect layer 340 unlike what is illustrated in FIG. 3.

The gate structures (342, 344, 345) may form transistors such as the transfer transistors (TX1, TX2), the reset transistor (RX), the amplification transistor (SF), and the selection transistor (SX) of FIG. 2 together with the source/drain regions of the substrate layer 310.

The interlayer insulation layer 348 may be an insulation material layer covering the gate structures (342, 344, 345) on the second surface (310b).

FIG. 4B is a cross-sectional view illustrating an example of the image sensing device 300 based on some embodiments of the disclosed technology. FIG. 4B is a cross-sectional view illustrating the image sensing device 300 taken along the line II-II’ of FIG. 3 based on some embodiments of the disclosed technology.

In some implementations, the image sensing device 300 may include an impurity region 315 in a region adjacent to a first surface (310a) of the substrate layer 310. For example, the impurity region 315 may be a region that is in contact with the first surface (310a) and is doped to a preset depth from the first surface (310a). The impurity region 315 may include impurities of the first conductivity type. The impurity concentration of the impurity region 315 may be higher than the impurity concentrations of the first semiconductor region (310r1) and the second semiconductor region (310r2). The impurity region 315 may be disposed in the semiconductor bridge region (310br). In a space between the first photoelectric conversion region (PD1) and the second photoelectric conversion region (PD2) adjacent to each other in the first direction (X), the first protrusion region (320p1), the impurity region 315 of the semiconductor bridge region (310br), and the second protrusion region (320p2) may be arranged side by side in the second direction (Y). The impurity region 315 together with the protrusion region (320p) of the pixel isolator 320 may prevent or hinder charge transfer between the first photoelectric conversion region (PD1) and the second photoelectric conversion region (PD2) of the second conductivity type. For example, the impurity region 315 may be doped with relatively high concentration impurities of a conductivity type opposite to those of the first photoelectric conversion region (PD1) and the second photoelectric conversion region (PD2), the impurity region 315 may prevent or hinder charge transfer between the photoelectric conversion regions.

Since the second insulation region (321b) having a second width (t2) less than the first width (t1) of the first insulation region (321a) between the first semiconductor region (310r1) and the second semiconductor region (310r2) is formed, a relatively large amounts of impurities may be doped in a subsequent process for forming the impurity region 315, thereby effectively improving charge transfer between the first photoelectric conversion region (PD1) and the second photoelectric conversion region (PD2). In addition, the process difficulty in formation of the impurity region 315 may be improved. Accordingly, the image sensing device 300 with improved performance or productivity may be provided.

In addition, as the insulation layer 321 within the protrusion region (320p) is formed to have a relatively small width, the dark current between the first semiconductor region (310r1) and the second semiconductor region (310r2) may be efficiently improved. For example, when a negative(-) voltage is applied to the filler layer 322 in order to improve the dark current of the surfaces of the first and second semiconductor regions (310r1, 310r2) in the future, a relatively high voltage is applied to the semiconductor region adjacent to the protrusion region (320p) where the insulation layer 321 has a small width, so that the dark current can be efficiently improved. Accordingly, the image sensing device with improved autofocus performance may be provided.

The image sensing device 300 according to an exemplary embodiment may further include an anti-reflection layer (not shown) on the first surface (310a) of the substrate layer 310, a grid (not shown) on the anti-reflection layer, a color filter layer (not shown) covering the grid, and a microlens layer (not shown) on the color filter layer.

The anti-reflection layer may be disposed between the first surface (310a) of the substrate layer 310 and the color filter to prevent reflection of light so that incident light can smoothly reach the photoelectric conversion regions (PD1, PD2). The grid may be disposed to vertically overlap the pixel isolator 320. The grid may guide incident light to be incident upon the photoelectric conversion regions (PD1, PD2). The grid may include a conductive material. The color filter layer includes color filters that respectively cover individual unit pixels and may include color filters that transmit colors of green, red and blue. The above color filter may filter a wavelength of light received by the photoelectric conversion regions (PD1, PD2) to determine the type of the unit pixel. The color filter may have a portion that overlaps the first photoelectric conversion region (PD1) in a plane and another portion that overlaps the second photoelectric conversion region (PD2) in a plane. That is, one color filter may correspond to two photoelectric conversion regions (PD1, PD2) within one unit pixel.

The microlens layer may be disposed on the color filter layer. The microlens layer may include an array of microlenses covering the unit pixels, respectively. Each microlens may have a convex shape and may have a predetermined radius of curvature. The microlens may collect incident light to transmit the incident light into each unit pixel to reach to the first photoelectric conversion region (PD1) and the second photoelectric conversion region (PD2). The microlens may have a portion that overlaps the first photoelectric conversion region (PD1) in a plane and another portion that overlaps the second photoelectric conversion region (PD2) in a plane. That is, one microlens may correspond to two photoelectric conversion regions (PD1, PD2) within one unit pixel. The microlens may include, for example, a light transmissive resin.

Hereinafter, the image sensing devices according to the above-described embodiment of the disclosed technology and other embodiments will be described. Hereinafter, a description will be given focusing on another embodiment of the pixel isolator, but it can be understood that a plurality of unit pixels is substantially the same as those described above.

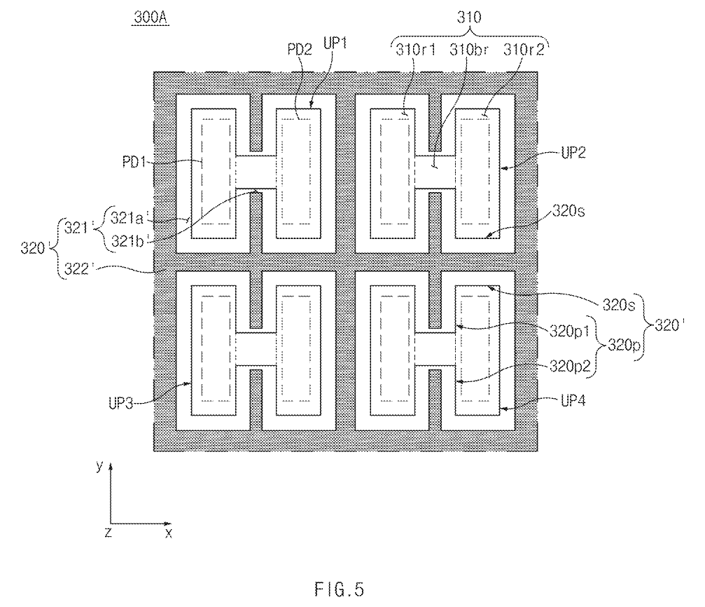

FIG. 5 is a plan view illustrating an example of an image sensing device 300A based on some embodiments of the disclosed technology.

Referring to FIG. 5, the image sensing device 300A may include a second insulation region (321b’) disposed only on a side surface of the semiconductor bridge region (310br), unlike the second insulation region (321b) of the image sensing device 300 of FIG. 4. In this case, the second insulation region (321b’) having a second width (t2) (see FIG. 3) may not have a portion extending onto the side surface of the first semiconductor region (310r1) and the side surface of the second semiconductor region (310r2). For example, a portion of the first insulation region (321a’) having the first width (t1) (see FIG. 3) may extend between the first semiconductor region (310r1) and the second semiconductor region (310r2).

As a second insulation region (321b’) having a relatively small width is arranged on a semiconductor bridge region (310br), the image sensing device 300A may be provided in which the doping concentration of the impurity region 315 is increased or the process difficulty is alleviated compared to the same process time.

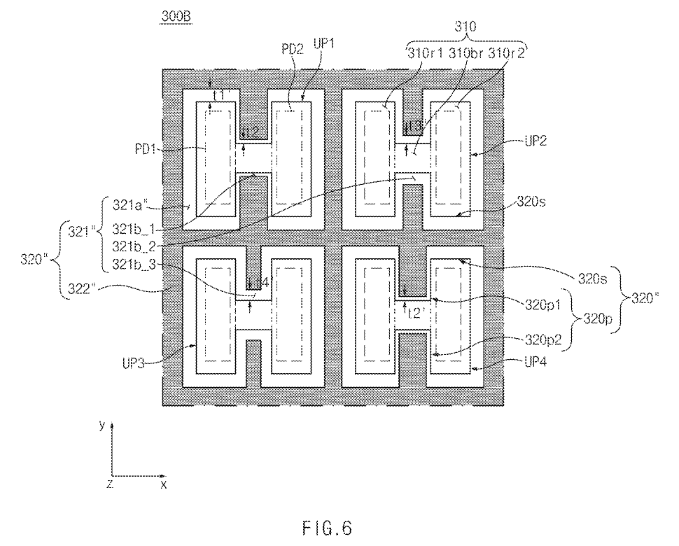

FIG. 6 is a plan view illustrating an example of an image sensing device 300B based on some embodiments of the disclosed technology.

Referring to FIG. 6, the image sensing device 300B may include an insulation layer (321”') having regions with different widths on adjacent side surfaces according to the types of the plurality of unit pixels (UP1, UP2, UP3, UP4).

The plurality of unit pixels (UP1, UP2, UP3, UP4) may include a first unit pixel (UP1), a second unit pixel (UP2), a third unit pixel (UP3), and a fourth unit pixel (UP4). For example, the first unit pixel (UP1) may be a green pixel, the second unit pixel (UP2) may be a red pixel, and the third unit pixel (UP3) may be a blue pixel.

The insulation layer (321”) may include a first insulation region (321a”), a second insulation region (321b_1), a third insulation region (321b_2), and a fourth insulation region (321b_3).

The first insulation region (321a”) may surround the plurality of unit pixels (UP1, UP2, UP3, UP4), and may distinguish the plurality of unit pixels (UP1, UP2, UP3, UP4) from each other. For example, the first insulation region (321a”) may be disposed between the first unit pixels (UP1) and the second unit pixels (UP2) adjacent to each other. The first insulation region (321a”') may have a first width (t1’).

The second insulation region (321b_2) may be disposed between the first semiconductor region (310r1) of the first unit pixel (UP1) and the second semiconductor region (310r2) of the first unit pixel (UP1). The second insulation region (321b_1) may have the same or similar characteristics to the second insulation region (321b_1) described in FIG. 3, except that the second insulation region (321b_1) has the second width (t2’). The second width (t2’) may be a different width from the first width (t1’).

The third insulation region (321b_2) may be disposed between the first semiconductor region (310r1) of the second unit pixel (UP2) and the second semiconductor region (310r2) of the second unit pixel (UP2). The third insulation region (321b_2) may have the same or similar characteristics to the second insulation region (321b) described in FIG. 3 except that the third insulation region (321b_2) has the third width (t3’). The third width (t3’) may be a different width from the first width (t1’) and the second width (t2’).

The fourth insulation region (321b_3) may be disposed between the first semiconductor region (310r1) of the third unit pixel (UP3) and the second semiconductor region (310r2) of the third unit pixel (UP3). The fourth insulation region (321b_3) may have the same or similar characteristics as the second insulation region (321b) described in FIG. 3, except that the fourth insulation region (321b_3) has a fourth width (t4’). The fourth width (t4’) may be different from each of the first to third widths (t1’, t2’,t3’).

The fourth width (t4’) may be greater than each of the second width (t2’) and the third width (t3’). The third width (t3’) may be greater than the second width (t2’).

The sensitivity of the unit pixels to light may vary depending on their types. For example, a green pixel may exhibit higher sensitivity than a red pixel, and the red pixel may exhibit higher sensitivity than a blue pixel. To improve uniformity in this case, the sensitivity of green pixels with relatively high sensitivity is reduced, while the sensitivity of blue pixels with relatively low sensitivity is increased. This adjustment can improve the uniformity of sensitivity across different unit pixels having different colors, thereby reducing noise and improving the overall performance of the image sensing device.

In some implementations, a width of the insulation region of the insulation layer (321”) may be adjusted differently for each type of the unit pixels to improve the uniformity of the sensitivity characteristics. As the width of the insulation layer (321”) adjacent to the unit pixel increases, the sensitivity characteristics of the unit pixels may be improved by reducing adjacent noise. Therefore, the uniformity of the sensitivity characteristics may be improved by adjusting the width of the insulation layer adjacent to the blue pixel having relatively low sensitivity characteristics to a higher value. For example, the fourth width (t4’) of the third unit pixel (UP3), which is a blue pixel, may be greater than the third width (t3’) of the second unit pixel (UP2), which is a red pixel, and the third width (t3’) of the second unit pixel (UP2), which is a red pixel, may be greater than the second width (t2’) of the first unit pixel (UP1), which is a green pixel.

The first width (t1’) may be greater than each of the second to fourth widths (t2’,t3’,t4’).

In this case, the disclosed technology may provide the image sensing device 300B in which the doping characteristic of the impurity region 315 (see FIG. 4B) of the 2PD-pixel structure are improved and performance is also improved according to a difference in sensitivity.

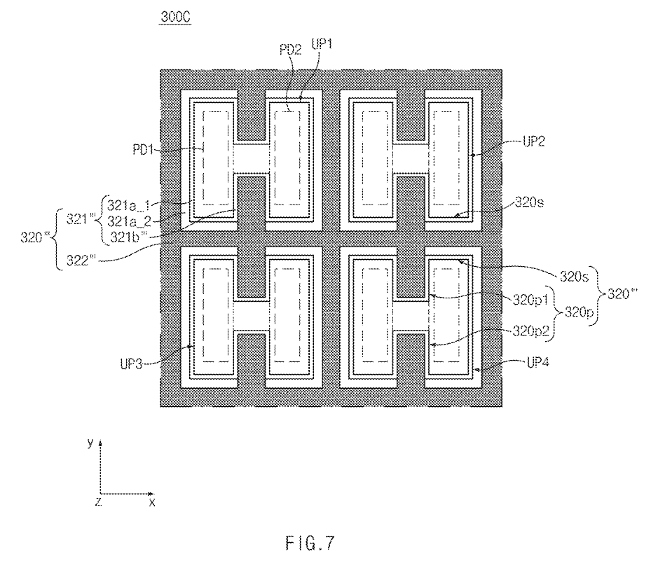

FIG. 7 is a plan view illustrating an example of the image sensing device 300C based on some embodiments of the disclosed technology.

Referring to FIG. 7, the image sensing device 300C may include first insulation regions (321a_1, 321a_2) having a multilayer structure of different materials.

The first insulation regions (321a_1, 321a_2) may include a first layer (321a_1) that is integrally connected to and extends from a second insulation region (321b”’), and a second layer (321a_2) on the first layer (321a_1). Each of the first layer (321a_1) and the second layer (321a_2) may include at least one of silicon oxide, silicon nitride, silicon oxynitride, aluminum oxide, tantalum oxide, and hafnium oxide. The first layer (321a_1) may have a width equal to a second width (t2) (see FIG. 3) of the second insulation region (321b”’), and a sum of the widths of the first layer (321a_1) and the second layer (321a_2) may be the first width (t1) (see FIG. 3). The first layer (321a_1) may be disposed in the circumferential region (320s) of the pixel isolator 320. The first layer (321a_1) may include the same material as the second insulation region (321b”’). In some implementations, the first layer (321a_1) may be formed in the same process as the process of forming the second insulation region (321b”’). The second layer (321a_2) may include a different material from the first layer (321a_1). However, depending on the embodiment, the second layer (321a_2) may include the same material as the first layer (321a_1). The second layer (321a_2) may be formed by performing a process separate from the process of forming the first layer (321a_1) and the second insulation region (321b”).

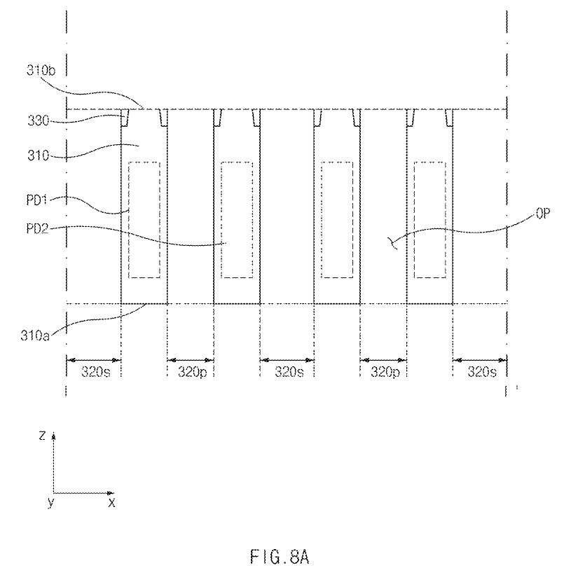

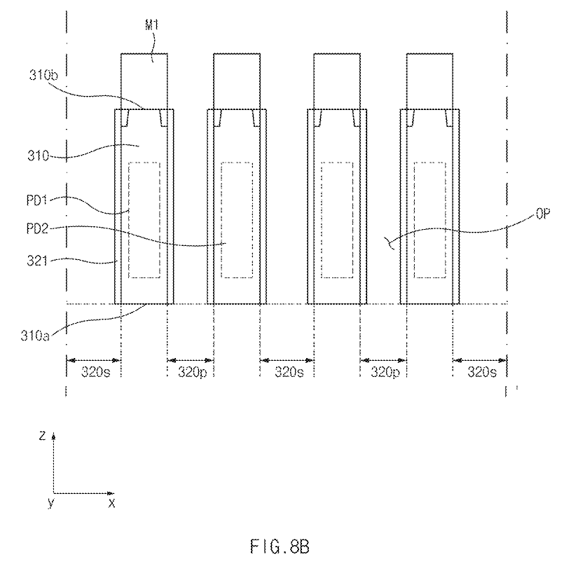

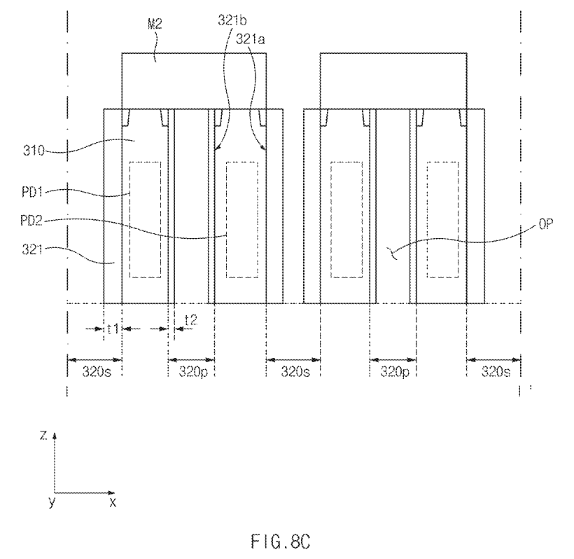

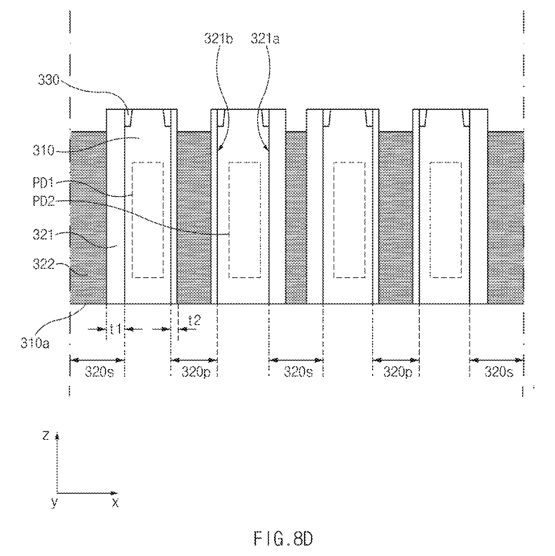

FIGS. 8A-8D are cross-sectional views illustrating examples of a method of manufacturing the image sensing device based on some embodiments of the disclosed technology. FIGS. 8A-8D are cross-sectional views illustrating examples of the image sensing device taken along the line I-I’ of FIG. 3.

Referring to FIG. 8A, a trench (OP) may be formed to penetrate the substrate layer 310 forming the first photoelectric conversion region (PD1) and the second photoelectric conversion region (PD2).

The trench (OP) may be formed by performing an anisotropic etching process on the second surface (310b) of the substrate layer 310. The trench (OP) may be formed by a single etching process using a mask for a region where the pixel isolator 320 of FIG. 3 is formed. Accordingly, a region corresponding to the circumferential region (320s) and the protrusion region (320p) of the pixel isolator 320 may be formed as an opening, and the side surface of the adjacent substrate layer 310 may be exposed.

Referring to FIG. 8B, an insulation layer 321 may be formed on the side surface of the exposed substrate layer 310 by performing a deposition process with an insulation material using the first mask (M1). The insulation layer 321 may have a constant width in the circumferential region (320s) and the protrusion region (320p) and may cover the exposed side surface of the substrate layer 310.

Referring to FIG. 8C, since a deposition process with the same material as the insulation material is performed using the second mask (M2) covering the protrusion region (320p), the width of the insulation layer 321 of the circumferential region (320s) may increase. Accordingly, the first insulation region (321a) having a first width (t1) in the circumferential region (320s) and a second insulation region (321b) having a second width (t2) less than the first width (t1) in the protrusion region (320p) may be formed.

As the planar shape of the second mask (M2) is changed, the image sensing devices implemented based on some embodiments of FIG. 5 or 6 may be provided.

In the deposition process of FIG. 8B and the deposition process of FIG. 8C, the image sensing device according to the embodiment of FIG. 7 may be provided by using different insulation materials.

However, according to embodiments, unlike FIGS. 8B and 8C, the mask shape may be changed so that the first insulation region (321a) of the circumferential region (320s) and the second insulation region (321b) of the protrusion region (320p) may be formed by separate deposition processes.

Referring to FIG. 8D, a filler layer 322 may be formed by performing a deposition process using a semiconductor material such as polycrystalline silicon. The filler layer 322 may be formed to have a lower height than the insulation layer 321 by performing a separate etching process or controlling the amount of deposition materials.

Thereafter, a capping layer 323 (see FIG. 4A) may be formed, an interconnect layer 340 (see FIG. 4A) may be formed on the second surface (310b), and an impurity region 315 (see FIG. 4B) may be formed in the semiconductor bridge region (310br) (see FIG. 4B) by doping impurities of the first conductivity type (e.g., p-type) on the first surface (310a). For example, the doping may be performed by plasma doping (PLAD). In this case, since a second insulation region (321b) having a relatively thin width compared to the first insulation region (321a) of the circumferential region (320s) is formed near the semiconductor bridge region (310br), performance or productivity may be improved, such as by increasing the doping concentration of the impurity region 315 or shortening the process time.

As is apparent from the above description, the image sensing device according to the embodiments of the disclosed technology may enable the insulation layers surrounding the unit pixels to have different widths according to positions of the insulation layers so as to alleviate process difficulty in formation of an impurity region, so that the image sensing device has higher productivity.

The image sensing device according to the embodiments of the disclosed technology has higher autofocus performance by relatively increasing the doping concentration of the impurity region.

The image sensing device according to the embodiments of the disclosed technology includes a region in which a width of the insulation layer is changed depending on the type of the unit pixel, so that the image sensing device has higher sensitivity homogeneity.

The embodiments of the disclosed technology may provide a variety of effects capable of being directly or indirectly recognized through the above-mentioned patent document.

Those skilled in the art will appreciate that the disclosed technology may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a substrate including a first surface configured to receive incident light and a second surface opposite to the first surface;
a unit pixel supported by the substrate and including: a first photoelectric conversion region configured to generate an electrical signal in response to the incident light; and a second photoelectric conversion region spaced apart from the first photoelectric conversion region and configured to generate an electrical signal in response to the incident light; and
a pixel isolator disposed in a trench recessed from the second surface into the substrate, the pixel isolator including:
a first insulation region having a first width along a direction parallel to the substrate; and
a second insulation region having a second width that is different from the first width,
wherein the second insulation region is disposed between the first photoelectric conversion region and the second photoelectric conversion region.

2. The image sensing device according to claim 1, wherein:
the second width is less than the first width.

3. The image sensing device according to claim 1, wherein:
the first insulation region is integrally connected to the second insulation region.

4. The image sensing device according to claim 3, wherein:
the first insulation region and the second insulation region have a same height in a direction perpendicular to the first surface; and
the first insulation region is formed to surround the unit pixel together with the second insulation region.

5. The image sensing device according to claim 1, wherein the pixel isolator further includes:
a filler layer surrounding an outer surface of an insulation layer within the trench, the insulation layer including the first insulation region and the second insulation region.

6. The image sensing device according to claim 5, wherein:
the insulation layer includes at least one of silicon oxide, silicon nitride, silicon oxynitride, aluminum oxide, tantalum oxide, or hafnium oxide; and
the filler layer includes a semiconductor material.

7. The image sensing device according to claim 5, wherein:
the pixel isolator further includes a capping layer disposed between the second surface of the substrate and the filler layer within the trench; and
the insulation layer extends from a side surface of the filler layer to a side surface of the capping layer.

8. The image sensing device according to claim 1, wherein:
the unit pixel includes a first semiconductor region including the first photoelectric conversion region, a second semiconductor region including the second photoelectric conversion region, and a semiconductor bridge region connecting the first semiconductor region and the second semiconductor region to each other;
the second insulation region is disposed on an outer surface of the semiconductor bridge region; and
the second width is less than the first width.

9. The image sensing device according to claim 8, wherein:
the first photoelectric conversion region is spaced apart from the second photoelectric conversion region in a first direction;
the first semiconductor region extends parallel to the second semiconductor region in a second direction perpendicular to the first direction; and
the second insulation region includes a portion extending from an outer side surface of the semiconductor bridge region to an outer side surface of the first semiconductor region, and a portion extending from the outer side surface of the semiconductor bridge region to an outer side surface of the second semiconductor region.

10. The image sensing device according to claim 1, further comprising:
an adjacent unit pixel adjacent to the unit pixel,
wherein the first insulation region is disposed between the unit pixel and the adjacent unit pixel,
wherein the second insulation region is disposed between the first photoelectric conversion region of the unit pixel and the second photoelectric conversion region of the unit pixel, and
wherein the pixel isolator further includes:
a third insulation region disposed between the first photoelectric conversion region of the adjacent unit pixel and the second photoelectric conversion region of the adjacent unit pixel, the third insulation region having a third width different from the first width and the second width.

11. The image sensing device according to claim 10, wherein:
the unit pixel is a red pixel configured to detect light within a red wavelength band;
the adjacent unit pixel is a green pixel configured to detect light within a green wavelength band;
the first width is greater than the second width; and
the second width is greater than the third width.

12. The image sensing device according to claim 10, wherein:
the unit pixel is a blue pixel configured to detect light within a blue wavelength band;
the adjacent unit pixel is a red pixel configured to detect light within a red wavelength band;
the first width is greater than the second width; and
the second width is greater than the third width.

13. The image sensing device according to claim 1, wherein:
the first insulation region is a multilayer structure including different materials; and
the second insulation region is a monolayer structure.

14. An image sensing device comprising:
a unit pixel that includes: a first semiconductor region including a first photoelectric conversion region configured to detect light; a second semiconductor region including a second photoelectric conversion region configured to detect light and spaced apart from the first semiconductor region in a first direction; and a semiconductor bridge region to connect the first semiconductor region and the second semiconductor region; and
a pixel isolator formed to surround the unit pixel and structured to include: a first insulation region having a first width and disposed along a side surface of the unit pixel; and a second insulation region having a second width less than the first width and disposed along another side surface of the unit pixel.

15. The image sensing device according to claim 14, wherein the pixel isolator includes:
a circumferential region; and
a protrusion region extending from the circumferential region to the semiconductor bridge region in a second direction perpendicular to the first direction,
wherein the first insulation region is disposed in the circumferential region, and
wherein the second insulation region is disposed in the protrusion region.

16. The image sensing device according to claim 15, wherein the pixel isolator further includes:
a filler layer surrounding an insulation layer including the first insulation region and the second insulation region,
wherein the filler layer includes a portion extending from the circumferential region to the protrusion region.

17. The image sensing device according to claim 14, wherein:
the first semiconductor region is connected to the semiconductor bridge region, and extends in a second direction perpendicular to the first direction;
the second semiconductor region is connected to the semiconductor bridge region, and extends in the second direction;
the second insulation region contacts a side surface of the first semiconductor region facing or opposite to the second semiconductor region; and
the first insulation region contacts at least a portion of a remaining side surface of the first semiconductor region.

18. An image sensing device comprising:
a substrate including a first surface configured to receive incident light and a second surface opposite to the first surface;
a unit pixel that is supported by the substrate and includes: a first semiconductor region including a first photoelectric conversion region configured to detect light ; a second semiconductor region including a second photoelectric conversion region configured to detect light, the second semiconductor region being spaced apart from the first semiconductor region in a first direction; and a semiconductor bridge region disposed between the first semiconductor region and the second semiconductor region;
a pixel isolator disposed in a trench recessed from the second surface into the substrate and including an insulation layer surrounding the unit pixel and a filler layer surrounding the insulation layer; and
an interconnect layer disposed on the second surface of the substrate,
wherein the insulation layer includes:
a first insulation region having a first thickness in a circumferential region; and
a second insulation region having a second thickness in a protrusion region protruding from the circumferential region to the semiconductor bridge region in a second direction perpendicular to the first direction.

19. The image sensing device according to claim 18, wherein:
the first thickness is greater than the second thickness.

20. The image sensing device according to claim 18, wherein:
the first insulation region and the second insulation region include a same material; and
each of the first insulation region and the second insulation region conformally extends along a side surface of the unit pixel.
